(19) United States
(12) Patent Application Publication
(10) Pub. No.: US 2017/0067181 A1
(43) Pub. Date: Mar. 9, 2017

(54) PRODUCTION METHOD OF EPITAXIAL SILICON WAFER, VAPOR DEPOSITION EQUIPMENT AND VALVE

(71) Applicant: SUMCO CORPORATION, Tokyo (JP)

(72) Inventor: Naoyuki WADA, Tokyo (JP)

(73) Assignee: SUMCO CORPORATION, Tokyo (JP)

(21) Appl. No.: 15/255,849

(22) Filed: Sep. 2, 2016

(30) Foreign Application Priority Data
Sep. 9, 2015 (JP) 2015-177406

(51) Int. Cl. C30B 25/08; C30B 25/20; H01L 27/146; C23C 16/44; H01L 21/02; C30B 25/14; C30B 29/06

(52) U.S. Cl. CPC C30B 25/08; C30B 25/14; C30B 25/20; C30B 29/06; C23C 16/4405; C23C 16/4404; H01L 21/02381; H01L 21/02532; H01L 21/0262; H01L 21/02634; H01L 27/14683

(57) ABSTRACT

A method for producing an epitaxial silicon wafer comprises applying a vapor deposition on a silicon wafer to produce the epitaxial silicon wafer. Vapor deposition equipment, in which the vapor deposition is conducted, at least includes a chamber, and a hydrogen-chloride-gas supply apparatus that is in communication and connected with an inside of the chamber to supply hydrogen chloride gas into the chamber. A valve that includes a diaphragm for regulating a flow of the hydrogen chloride gas from an inlet channel to an outlet channel is disposed in the hydrogen-chloride-gas supply apparatus. A W-containing Ni—Cr—Mo alloy material subjected to a passivation treatment is used for the diaphragm. When a maintenance work is to be done to the inside of the chamber, the hydrogen chloride gas is supplied from the hydrogen-chloride-gas supply apparatus into the chamber.

The entire disclosure of Japanese Patent Application No. 2015-177406 filed Sep. 9, 2015 is expressly incorporated by reference herein.

### TECHNICAL FIELD

The present invention relates to a production method of an epitaxial silicon wafer, vapor deposition equipment and a valve.

### BACKGROUND ART

Recently, substrates of image pickup devices such as CCD and CIS are often made of an epitaxial silicon wafer including an epitaxial layer provided by vapor deposition on a silicon wafer. It is crucially important for such an epitaxial silicon wafer for an image pickup device that an amount of heavy-metal impurities in the silicon wafer is lowered. This is because, when the heavy-metal impurities are present in a wafer, so-called white defects (defects in device characteristics, which are unique to an image pickup device) are caused.

During the production of epitaxial silicon wafers using vapor deposition, H₂ and Si material gases are used for the vapor deposition of the epitaxial layer. By-products are also generated during the vapor deposition, which are deposited in a chamber. The deposited by-products are a source of contamination. Accordingly, in order to remove the by-products, the chamber is regularly cleaned. Hydrogen chloride gas is used as a cleaning gas.

Even when a highly anti-corrosive metal is used for a component of vapor deposition equipment, since hydrogen chloride gas is highly corrosive, the component of the vapor deposition equipment still corrodes in an atmosphere of highly-concentrated hydrogen chloride gas. Then, metal contaminant (e.g. metal chloride) caused by the corrosion is introduced into the wafer and, consequently, the produced epitaxial silicon wafer is contaminated with the metal.

In order to reduce the metal contamination caused by the vapor deposition equipment, it has been proposed to cover a part of vapor deposition equipment components, which is made of a material containing metal and is to be in contact with the gas, with a non-metal protection film and to use an O-ring not containing Ti at a connecting portion of each of the components (see Patent Literature 1: JP-A-2010-135388). According to Patent Literature 1, since a contact of gas and metal can be prevented with the use of the above-described vapor deposition equipment, the metal contamination can be avoided. Consequently, it is reported that a high-quality epitaxial silicon wafer with small number of white defects, total concentration of four elements of Mo, W, V and Nb is 4×10¹⁰/cm³ or less, and Ti concentration of 3×10¹²/cm³ or less can be produced.

However, according to the method disclosed in the above Patent Literature 1, since it is necessary to regularly renew the coating of the component(s) coated with the non-metal protection film in accordance with a use frequency, complicated work has to be done each time the regular re-coating is done. Further, it is expected to be difficult in terms of the design to completely cover an entirety of the metal component(s) that is to be in contact with gas using a protection film.

### SUMMARY OF THE INVENTION

An object of the invention is to provide a production method of an epitaxial silicon wafer, vapor deposition equipment and a valve that are capable of easily restraining generation of white defects.

A method for producing an epitaxial silicon wafer according to an aspect of the invention includes: applying a vapor deposition on a silicon wafer to produce an epitaxial silicon wafer, where vapor deposition equipment, in which the vapor deposition is conducted, at least comprises a chamber, and a hydrogen-chloride-gas supply apparatus that is in communication and connected with an inside of the chamber to supply hydrogen chloride gas into the chamber, a valve that comprises a diaphragm configured to regulate a flow of the hydrogen chloride gas from an inlet channel to an outlet channel is disposed in the hydrogen-chloride-gas supply apparatus, a material of a W-containing Ni—Cr—Mo alloy subjected to a passivation treatment is used for the diaphragm, and when a maintenance work is to be done to an inside of the chamber, the hydrogen chloride gas is supplied from the hydrogen-chloride-gas supply apparatus into the chamber.

Vapor deposition equipment according to another aspect of the invention is configured to apply a vapor deposition on a silicon wafer to produce an epitaxial silicon wafer, the vapor deposition equipment at least including: a chamber; and a hydrogen-chloride-gas supply apparatus that is in communication and connected with an inside of the chamber to supply hydrogen chloride gas into the chamber, where a valve that comprises a diaphragm configured to regulate a flow of the hydrogen chloride gas from an inlet channel to an outlet channel is disposed in the hydrogen-chloride-gas supply apparatus, a material of a W-containing Ni—Cr—Mo alloy subjected to a passivation treatment is used for the diaphragm, and, when a maintenance work is to be done to an inside of the chamber, the hydrogen chloride gas is supplied from the hydrogen-chloride-gas supply apparatus into the chamber.

According to the above aspect of the invention, the material including a corrosion-resistant oxidation film formed on the surface thereof, whose thickness is increased by the passivation treatment applied on the W-containing Ni—Cr—Mo alloy, is used for the diaphragm of the valve in the hydrogen-chloride-gas supply apparatus. As described above, since the thickness of the corrosion-resistant oxidation film is increased by surface modification of the Ni—Cr—Mo alloy, a frequency for chemical reprocessing for enhancing corrosion resistance can be decreased as compared to an instance where a protection film is formed by coating. Further, since the corrosion of the diaphragm of the valve is restrained when a highly corrosive hydrogen chloride gas is supplied by the hydrogen-chloride-gas supply apparatus during the chamber cleaning, W (i.e. an element supposed to greatly contribute to the generation of white defects) is not eluted. Since the W contamination from the hydrogen-chloride-gas supply apparatus to the chamber during the chamber cleaning can be reduced as described above, a high quality epitaxial silicon wafer that is capable of restraining the generation of white defects can be easily produced with the use of the above vapor deposition equipment.

In the method for producing an epitaxial silicon wafer according to the above aspect of the invention, it is preferable that the valve including the diaphragm is a pressure regulator valve configured to regulate a pressure of the hydrogen chloride gas flowing therein, and the material of the W-containing Ni—Cr—Mo alloy subjected to the passivation treatment is used for a component defining a channel in the pressure regulator valve.

In the vapor deposition equipment according to the above aspect of the invention, it is preferable that the valve comprising the diaphragm is a pressure regulator valve configured to regulate a pressure of the hydrogen chloride gas flowing therein, and the material of the W-containing Ni—Cr—Mo alloy subjected to the passivation treatment is used for a component defining a channel in the pressure regulator valve.

According to the above arrangement, since the W-containing Ni—Cr—Mo alloy subjected to the passivation treatment is used for the component defining the channel in the pressure regulator valve, W contamination derived from the pressure regulator valve can be restrained. Consequently, the introduction of the W contamination from the hydrogen-chloride-gas supply apparatus into the chamber can be further reduced, whereby an epitaxial silicon wafer with extremely small W concentration in the epitaxial layer can be provided.

A valve according to still another aspect of the invention includes a diaphragm configured to regulate a flow of a gas from an inlet channel to an outlet channel, in which the diaphragm comprises a material of a W-containing Ni—Cr—Mo alloy subjected to a passivation treatment.

According to the above aspect of the invention, a valve applicable to a production method of an epitaxial silicon wafer and vapor deposition equipment that are capable of easily producing a high-quality epitaxial silicon wafer with restrained generation of white defects can be provided.

### BRIEF DESCRIPTION OF DRAWING(S)

FIG. 1 is a schematic illustration showing a hydrogen-chloride-gas supply apparatus of vapor deposition equipment according to an exemplary embodiment.

FIG. 2 shows an overall arrangement of a diaphragm valve.

FIG. 3 is a schematic illustration showing a diaphragm of the diaphragm valve.

FIG. 4 shows an overall arrangement of a pressure regulator valve.

FIG. 5 is a graph showing a metal elution amount from each of a used pipe (welded and non-welded) and a new pipe.

FIG. 6 shows EDX analysis results of the diaphragm of the diaphragm valve.

FIG. 7 is a graph showing a result of comparison of a metal composition ratio between unused and used diaphragms in the diaphragm valve.

FIG. 8 shows EDX analysis results of the diaphragm of the pressure regulator valve.

FIG. 9 is a graph showing a result of comparison of a metal composition ratio between unused and used diaphragms in the pressure regulator valve.

FIG. 10 shows a relationship between presence/absence of a white defect and a concentration of W or Mo.

FIG. 11 is a graph showing a relationship between presence/absence of passivation treatment and the metal elution amount after a forced corrosion test in Example 1.

FIG. 12 shows GD-OES analysis results of a sample not subjected to the passivation treatment in Example 2.

FIG. 13 shows GD-OES analysis results of a sample subjected to the passivation treatment in Example 2.

### DESCRIPTION OF EMBODIMENT(S)

An exemplary embodiment of the invention will be described below with reference to the attached drawings.

In order to solve the above problem(s), the inventors of the invention have conducted vigorous studies on the source of contamination that causes the white defects.

The hydrogen chloride gas used in order to clean the chamber is highly corrosive, though having a great effect for removing by-products. Accordingly, it is speculated that a metal contamination, which is caused when a hydrogen-chloride-gas supply apparatus for supplying hydrogen chloride gas is corroded by the hydrogen chloride gas, is introduced into a chamber to exert a great influence on the white defect characteristics of image pickup products.

Further, though it has been speculated that the primary source of contamination that causes the white defects is metal such as Mo, W, Ti, Nb, and Ta, the inventors have found that, among the metal contaminants, W contamination exerts the greatest influence on generation of the white defects.

Accordingly, the inventors have focused and studied on the hydrogen-chloride-gas supply apparatus for supplying hydrogen chloride gas into the chamber when the chamber is cleaned, and W as the contamination metal.

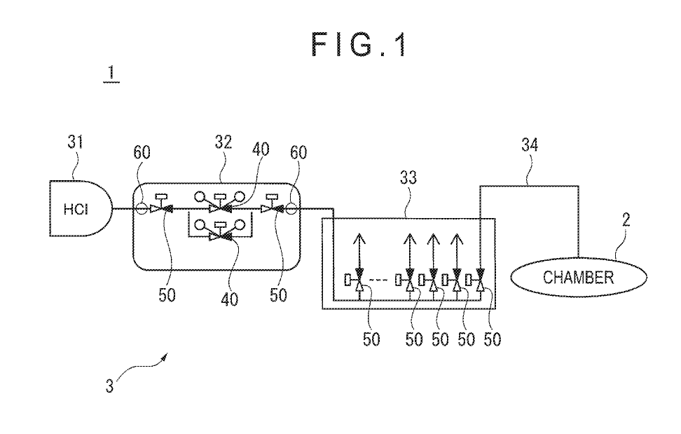

As shown in FIG. 1, vapor deposition equipment 1 of the exemplary embodiment, in which vapor deposition is applied, at least includes a chamber 2, and a hydrogen-chloride-gas supply apparatus 3 that is in communication and connected with an inside of the chamber 2 to supply hydrogen chloride gas into the chamber 2. The hydrogen-chloride-gas supply apparatus 3 is provided in order to supply hydrogen chloride gas into the chamber 2 when the chamber 2 is cleaned.

The hydrogen-chloride-gas supply apparatus 3 includes a hydrogen-chloride-gas supply unit 31, a decompression unit 32 and a valve manifold box 33 (VMB). The hydrogen-chloride-gas supply apparatus 3 is in communication and connected with the chamber 2 through a pipe 34, in which the hydrogen chloride gas flows.

The decompression unit 32 is installed therein with a pressure regulator valve 40, a diaphragm valve 50, and a pressure gauge 60. The pressure regulator valve 40 controls the pressure of the hydrogen chloride gas flowing therethrough. The diaphragm valve 50 regulates the flow rate of the hydrogen chloride gas with a diaphragm. The pressure gauge 60 measures pressures of the hydrogen chloride gas before and after being decompressed by the pressure regulator valve 40.

It should be noted that, though the decompression unit 32 shown in FIG. 1 includes the two-stage pressure regulator valve 40, the decompression unit 32 may have a single-stage arrangement for the pressure regulator valve 40.

The pipe 34 is branched into a plurality of pipes in the VMB 33, and the diaphragm valve 50 is provided to each of the branched pipes 34. The pipes 34 branched in the VMB 33 are respectively connected to a plurality of the chambers 2, so that the hydrogen chloride gas can be supplied to the plurality of the chambers 2 from the single hydrogen-chloride-gas supply apparatus 3.

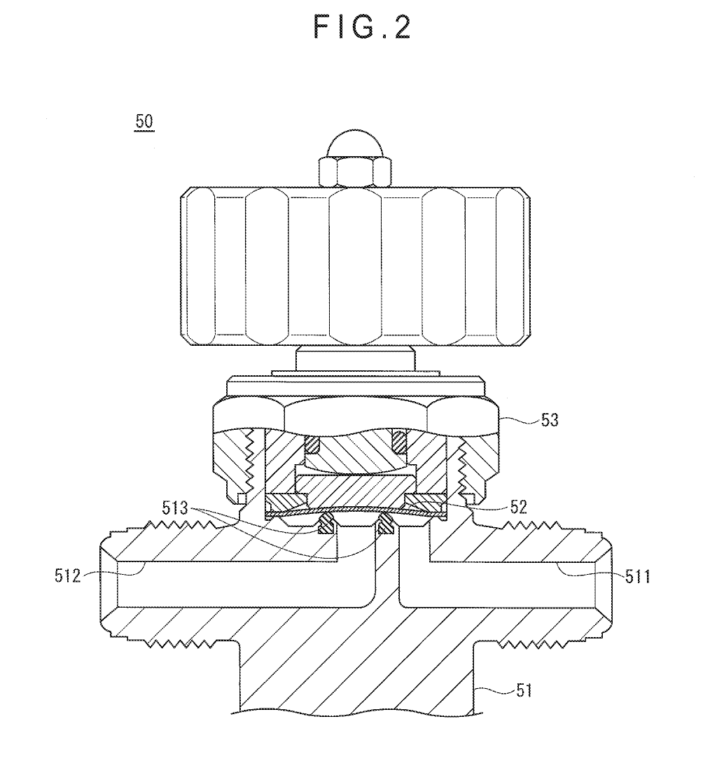

FIG. 2 shows an overall arrangement of the diaphragm valve 50.

The diaphragm valve 50 includes a body portion 51, a diaphragm 52 and a drive portion 53. The body portion 51 is provided with an inlet channel 511 and an outlet channel 512, both of which define a channel for the hydrogen chloride gas, and a valve seat 513 to be in contact with the diaphragm 52. The diaphragm 52 is disposed to cover the inlet channel 511, the valve seat 513 and the outlet channel 512 of the body portion 51. The drive portion 53 is connected with the body portion 51 through the diaphragm 52 to lift and press the diaphragm 52.

The diaphragm valve 50 allows or blocks the communication between the inlet channel 511 and the outlet channel 512 of the body portion 51 by lifting the diaphragm 52 or pressing the diaphragm 52 onto the valve seat 513 of the body portion 51 using the drive portion 53.

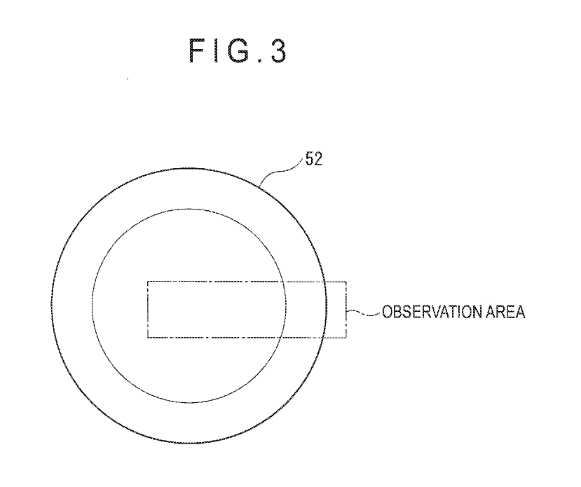

FIG. 3 is a plan view of the diaphragm 52. As shown in FIG. 3, the diaphragm 52 has a dented shape, thereby receiving a stress when the diaphragm valve 50 is opened or closed. Accordingly, the diaphragm 52 is likely to be corroded when the hydrogen chloride gas flows. It is speculated that the corroded portion is gasified to be introduced into the chamber 2.

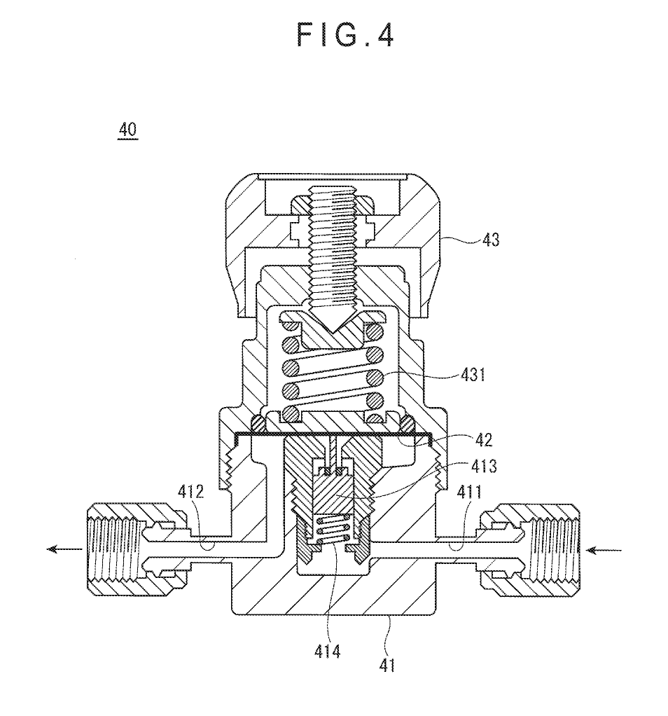

FIG. 4 is a cross section showing an overall arrangement of the pressure regulator valve 40.

The pressure regulator valve 40 includes a body portion 41, a diaphragm 42 and a pressure-adjustment handle 43. The body portion 41 is provided with an inlet channel 411 and an outlet channel 412, which define a channel for the hydrogen chloride gas, a seat 413 and a seal spring 414. The diaphragm 42 is disposed to he in contact with the seat 413 and to cover the inlet channel 411 and the outlet channel 412. The pressure-adjustment handle 43 is connected with the body portion 41 through the diaphragm 42 and includes a pressure-adjustment spring 431 that effects a pressure adjustment.

Corresponding to a fastening degree of the pressure-adjustment handle 43, a physical force is applied from the pressure-adjustment spring 431 to the diaphragm 42. A space volume of an area to be in contact with the flowing hydrogen chloride gas is thereby adjusted to effect the pressure adjustment (decompression). Since the pressure adjustment is repeatedly conducted, the component (e.g. the seat 413) defining the channel in the pressure regulator valve 40 and the diaphragm 42 are likely to be corroded when the hydrogen chloride gas flows. In the same manner as the diaphragm valve 50, it is speculated that the corroded portion is gasified to be introduced into the chamber 2.

Study on Pipe

The following evaluation test was conducted for the pipe 34 of the hydrogen-chloride-gas supply apparatus 3.

Initially, a pipe used for a plurality of times (referred to as a used pipe hereinafter) and an unused pipe (referred to as a new pipe hereinafter) were prepared. The pipe was made of SUS3166L. It should be noted that two types of the used pipe (i.e. welded and non-welded) were examined. Then, the hydrogen chloride gas was supplied from the hydrogen-chloride-gas supply apparatus 3 installed with these pipes into the chamber 2.

Next, after the hydrogen chloride gas was supplied, an image of the surface of the inside of the pipe was taken using a Scanning Electron Microscope (SEM). Then, since SUS316L was inferior in corrosion resistance, both of the used and new pipes showed slight corrosion. In the above, it was observed that the used pipe was more corroded.

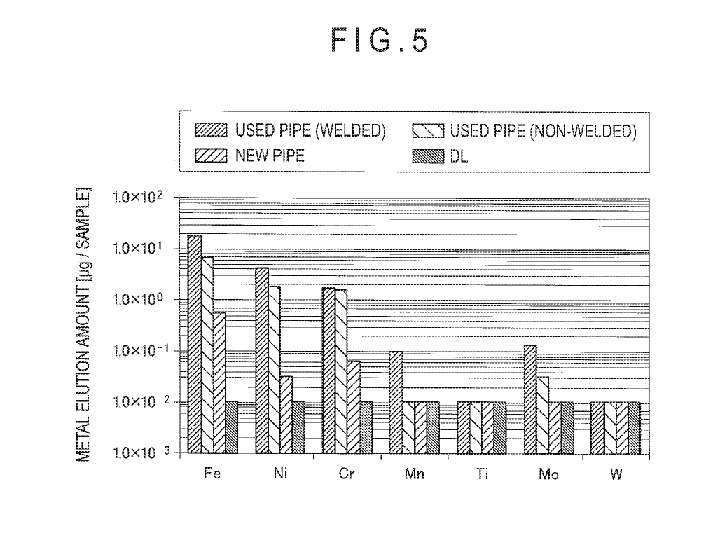

Further, for samples prepared after the hydrogen chloride gas was supplied (i.e. after the chamber was cleaned), metal analysis was performed according to Inductively Coupled Plasma Mass Spectrometry (ICP-MS). According to the results of the metal analysis, it can be determined whether or not metals (Fe, Ni, Cr, Mn, Ti, Mo, W) are detected in the samples (i.e. whether or not the metals are eluted from the pipe). The results are shown in FIG. 5. Incidentally, DL in FIG. 5 denotes a detection limit.

As shown in FIG. 5, the metals such as Fe, Ni, Cr and Mo were detected in both of the used pipe and the new pipe. It should be noted that Mn was detected only in the welded used pipe and was not detected in non-welded used pipe or the new pipe. Further, since SUS316L contains no Ti and W, Ti and W were not detected in all of the pipes.

According to the above results, it can be concluded that SUS316L used as a material for the pipe 34 is not a source of contamination of W.

Study on Diaphragm Valve

Next, the following evaluation test was conducted for the diaphragm valve 50 of the hydrogen-chloride-gas supply apparatus 3. In view of a demand for more excellent acid and corrosion resistances for a material of the diaphragm as compared with the materials of the pipes, a Co—Ni—Cr—Mo alloys (SPRON 100 manufactured by Seiko Instruments Inc.: SPRON is a registered trademark), which is excellent in corrosion resistance, was used as a material for the diaphragm 52 of the diaphragm valve 50.

Hydrogen chloride gas was supplied from the hydrogen-chloride-gas supply apparatus 3 into the chamber 2. Subsequently, after the hydrogen chloride gas was supplied, an image of a surface (a side in contact with the hydrogen chloride gas) of the diaphragm 52 of the diaphragm valve 50 was taken by an SEM to find corrosion on the surface.

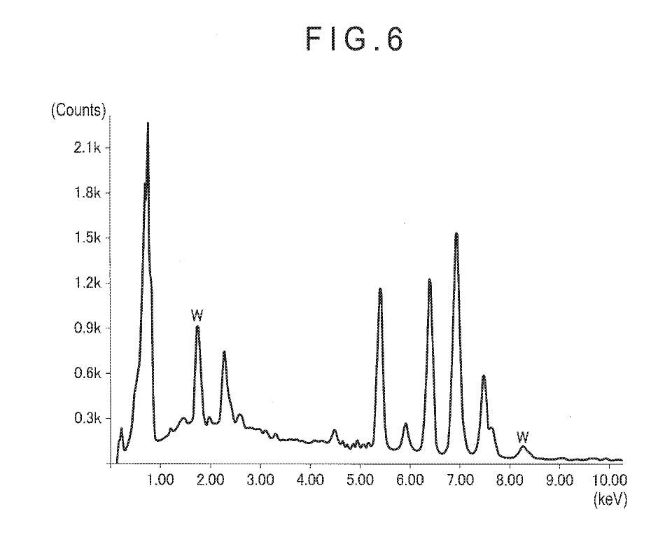

Further, the composition of the diaphragm 52 after the hydrogen chloride gas was supplied was analyzed using Energy Dispersive X-ray spectroscopy (EDX). Then, it was found that W was detected as shown in FIG. 6.

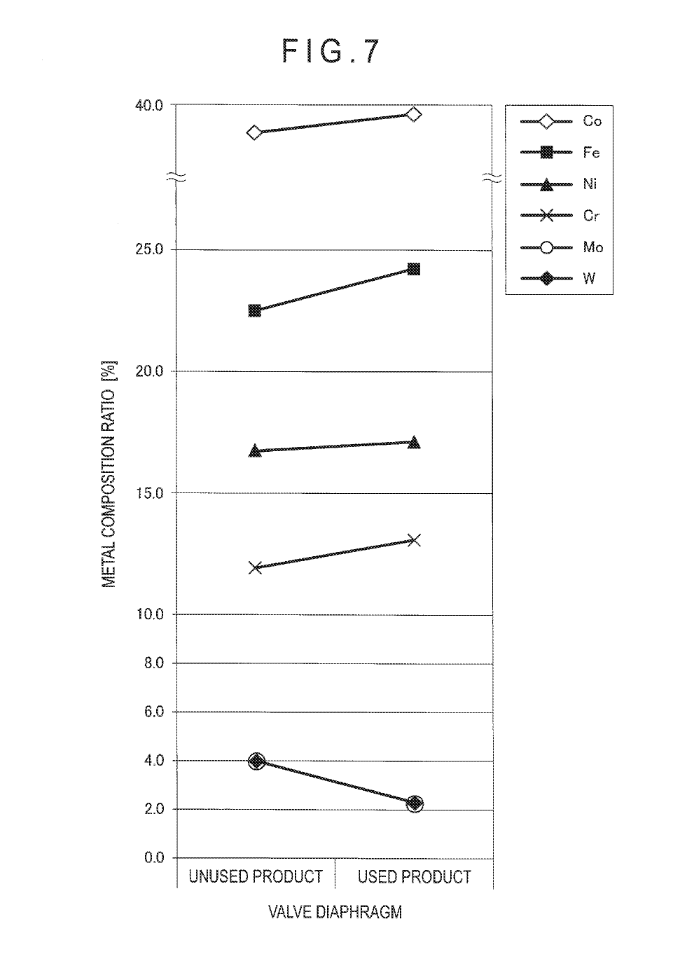

Next, a diaphragm used for a plurality of times (referred to as a used product hereinafter) and an unused diaphragm (referred to as an unused product hereinafter) were prepared. Then, the composition of these diaphragms was analyzed compare the ratios of the metal components of these diaphragms. The results are shown in FIG. 7. It should be noted that six metal elements (Co, Fe, Ni, Cr, Mo, W) of the metal components of the diaphragm 52 were compared in FIG. 7.

As shown in FIG. 7, it was observed that the composition ratio of Mo and W was lowered in the used product as compared with the unused product. From the results, it is speculated that the above elements of which composition ratio was reduced was introduced into the chamber 2 due to corrosion.

Study on Pressure Regulator Valve

Next, the following evaluation test was conducted for the pressure regulator valve 40 installed in the hydrogen-chloride-gas supply apparatus 3. As a material for the diaphragm 42 of the used pressure regulator valve 40, HASTELLOY C22 (a Ni—Cr—Mo alloy excellent in corrosion resistance, manufactured by Haynes International KK: HASTELLOY is a registered trademark) was used.

Hydrogen chloride gas was supplied from the hydrogen-chloride-gas supply apparatus 3 into the chamber 2. Subsequently, after the hydrogen chloride gas was supplied, an image of a surface of the diaphragm 42 of the pressure regulator valve 40 was taken by an SEM to find corrosion on the surface.

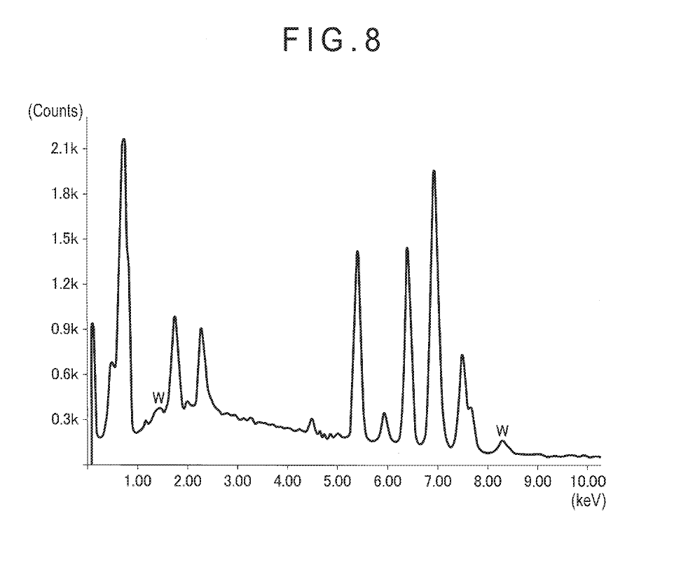

Further, the composition of the diaphragm 42 of the pressure regulator valve 40 after the hydrogen chloride gas was supplied was analyzed using EDX. Then, it was found that W was detected as shown in FIG. 8.

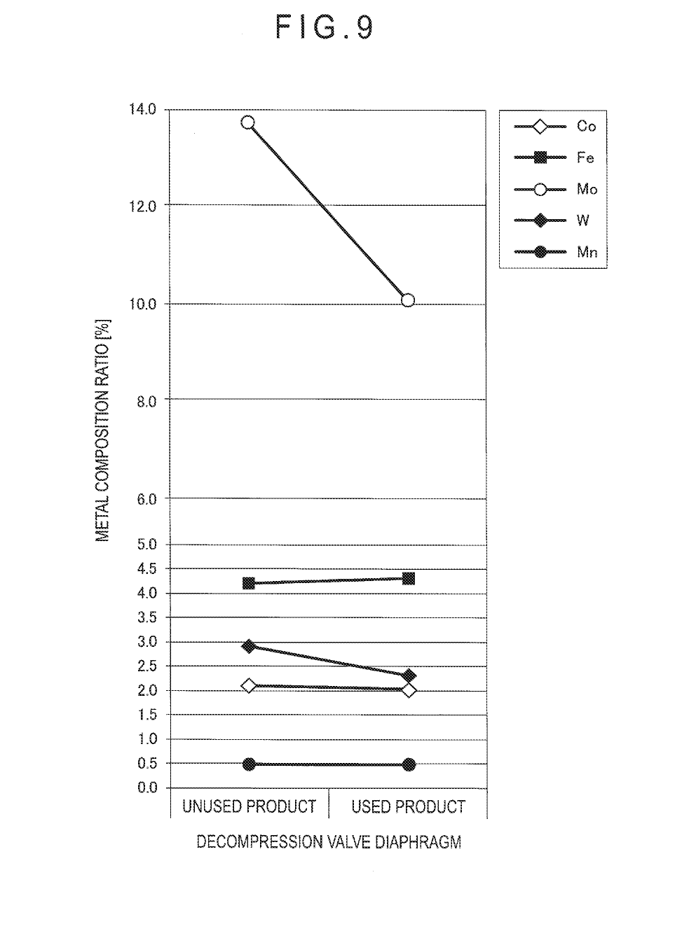

Subsequently, a used product and an unused product for the diaphragm 42 of the pressure regulator valve 40 were prepared and the composition of these diaphragms was analyzed to compare the metal composition ratio of the diaphragms. The results are shown in FIG. 9. It should be noted that five metal elements (Co, Fe, Mo, W, Mn) of the metal components of the diaphragm of the pressure regulator valve 40 were compared in FIG. 9.

As shown in FIG. 9, it was observed that the composition ratio of Mo and W was lowered in the used product as compared with the unused product. From the results, it is speculated that the above elements of which composition ratio was reduced was introduced into the chamber 2 due to corrosion.

Further, the material of a part of the components (e.g. the seat 413 defining the channel in the pressure regulator valve 40) of the pressure regulator valve 40 is typically the same as the material of the diaphragm 42. Accordingly, with regard to the used product, it is speculated that the contamination metal is also introduced into the chamber 2 due to the corrosion of these components.

Study on Types of Contamination Metal

Next, a sample epitaxial silicon wafer with no white defect being generated and a sample epitaxial silicon wafer with the white defects being generated were prepared and the concentrations of W and Mo on the surface of the epitaxial layer were measured using an ICP-MS.

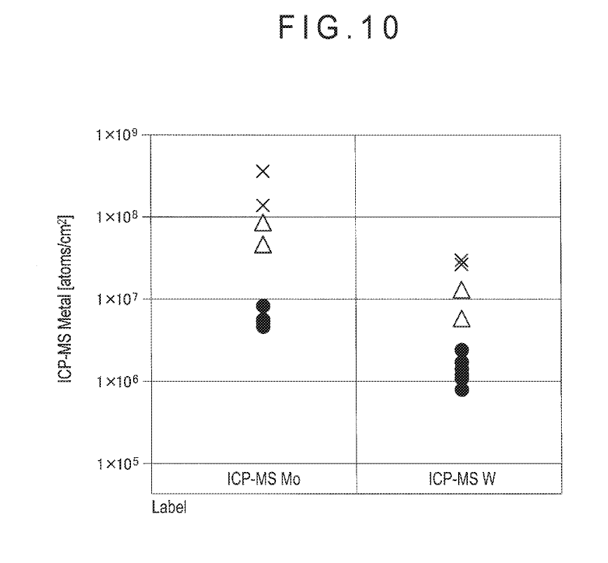

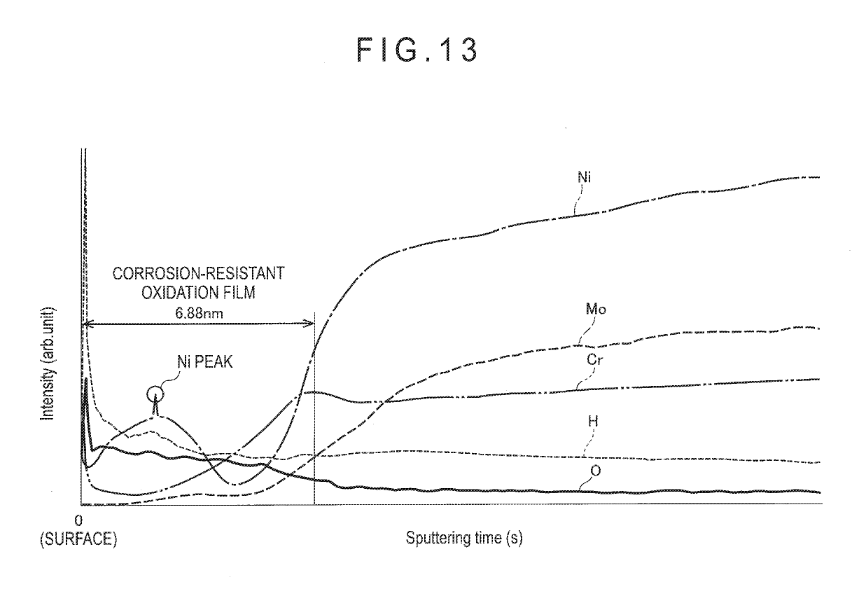

W concentration is shown on the right side of FIG. 10 and Mo concentration is shown on the left side of FIG. 13. In FIG. 10, a circle mark represents the sample with no white defect being generated, a triangular mark represents a sample that was determined to be usable for image pickup devices though with slight white defects being generated, and a cross mark represents a sample that was determined to be unable to be used for image pickup devices with white defects being generated thereon.

As shown in FIG. 10, the comparison between the W concentration and Mo concentration reveals that the white defects were not generated at Mo concentration around 1×10⁷ atoms/cm², whereas the white defects were not generated at W concentration of 5×10⁶ atoms/cm² or less. It is speculated from the results that W contamination contributes more to the generation of white defects than Mo contamination.

Based on the results of the evaluations on each of the components and the studies on the types of the contamination metal, it is speculated that, when the chamber is cleaned, the diaphragm 52 of the diaphragm valve 50 and/or the diaphragm 42 of the pressure regulator valve 40 are corroded and W is introduced from the hydrogen-chloride-gas supply apparatus 3 into the chamber 2, whereby the epitaxial silicon wafer is contaminated with W.

The invention has been reached based on the above findings.

In the production method of an epitaxial silicon wafer according to this exemplary embodiment, a material having a corrosion-resistant oxidation film, whose thickness is increased by passivation treatment applied on the W-containing Ni—Cr—Mo alloy, is used for the diaphragms 42, 52 of the pressure regulator valve 40 and the diaphragm valve 50 (i.e. the valve of this exemplary embodiment). Examples of the W-containing Ni—Cr—Mo alloy include HASTELLOY C22 typically used for the diaphragm 42 of the pressure regulator valve 40. Examples of the passivation treatment include an anode oxidation method, ozone oxidation method and strong oxidizer method.

Further, a W-containing Ni—Cr—Mo alloy subjected to the passivation treatment may be used for the component defining the channel in the pressure regulator valve 40 in the same manner as the diaphragms 42, 52.

Using the vapor deposition equipment 1 having the above hydrogen-chloride-gas supply apparatus 3, vapor deposition is applied on a silicon wafer to produce an epitaxial silicon wafer. When a maintenance work is to be done to the inside of the chamber 2, hydrogen chloride gas is supplied from the hydrogen-chloride-gas supply apparatus 3 into the chamber 2 (chamber cleaning). The diameter of the silicon wafer to be treated in the chamber 2 may be 200 mm, 300 mm or the like.

### Advantage(s) of Embodiment(s)

As described above, the above exemplary embodiment provides the following advantages.
(1) A W-containing Ni—Cr—Mo alloy subjected to the passivation treatment is used for the diaphragm 52 of the diaphragm valve 50 and the diaphragm 42 of the pressure regulator valve 40 in the hydrogen-chloride-gas supply apparatus 3. Accordingly, even when the highly corrosive hydrogen chloride gas is supplied by the hydrogen-chloride-gas supply apparatus 3 during the chamber cleaning, the corrosion on the diaphragms 42, 52 can be restrained, where W that is supposed to greatly contribute to the generation of white defects is not eluted. Accordingly, W contamination from the hydrogen-chloride-gas supply apparatus 3 to the chamber 2 can be decreased during the chamber cleaning. Consequently, with the use of the above vapor deposition equipment 1, a high quality epitaxial silicon wafer that is capable of restraining the generation of white defects can be easily produced.
(2) Since the W-containing Ni—Cr—Mo alloy subjected to the passivation treatment is used for the component defining the channel in the pressure regulator valve 40, W contamination derived from the pressure regulator valve 40 can be restrained. Consequently, W contamination introduced from the hydrogen-chloride-gas supply apparatus 3 to the chamber 2 can be further decreased.

### Other Embodiment(s)

It should be noted that the scope of the invention is not limited to the above-described exemplary embodiment(s), but can be variously modified or altered in design in a range compatible with an object of the invention. In addition, specific procedures and structures in implementing the invention may be altered as long as such an alteration is compatible with an object of the invention.

### EXAMPLE(S)

Next, the invention will be described below in further details with reference to Examples. It should be noted, however, that the scope of the invention is not limited by the Example(s).

### Example 1

Initially, a test piece (10 mm square, 1 mm thick) of HASTELLOY C22 (a W-containing Ni—Cr—Mo alloy) was prepared. The passivation treatment was subsequently applied on the test piece using the strong oxidizer method, where it was found that the test piece became glossy.

Next, a forced corrosion test was conducted on a sample of Example 1 in which the test piece was subjected to the passivation treatment and a sample of Comparative Example 1 in which the test piece was not subjected to the passivation treatment. Specifically, a tripod was placed upright in a beaker with aqueous hydrochloric acid (20% concentration) being put therein. The sample was paced on the tripnd so that the sample does not touch the aqueous hydrochloric acid. Then, after the beaker was covered with a lid and left in the gaseous phase space above the aqueous hydrochloric acid for five hours, the presence of corrosion was visually checked.

As a result, it was observed that the sample of Example 1 produced no significant corrosion and the glossiness did not change. On the other hand, it was observed that the surface of the sample of Comparative Example 1 was dulled though not significantly corroded.

As described above, it was observed that the passivation treatment applied on the W-containing Ni—Cr—Mo alloy improved corrosion resistance.

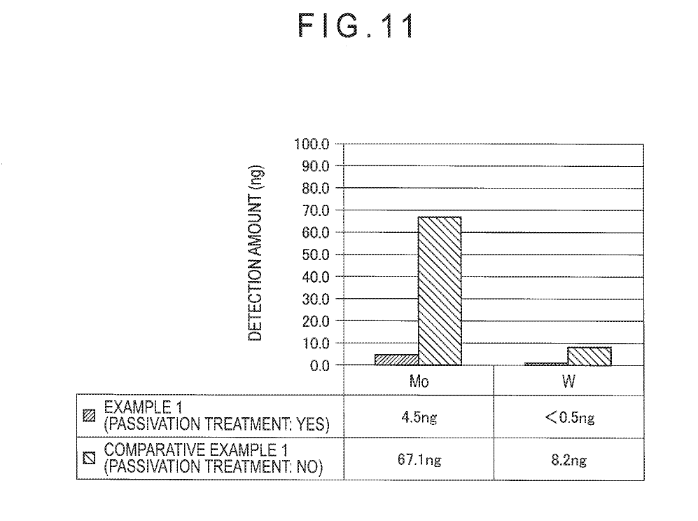

Next, metal elution amounts of the samples of the above Example 1 and Comparative Example 1 were measured. Specifically, the sample after being subjected to the forced corrosion test was immersed in 4 ml of pure water in a beaker and left for five minutes. Next, after the sample was taken out of the beaker, 1 ml of mixed acid was added in the beaker and the solution added with the mixed acid was subjected to an ICP-MS quantitative analysis. The results are shown in FIG. 11.

As shown in FIG. 11, it was observed that the passivation treatment considerably reduced the detectable amount of Mo and W. Especially, the elution amount of W was less than the detection limit (0.5 ng).

As described above, it was observed that the passivation treatment applied on the W-containing Ni—Cr—Mo alloy avoids the elution of W even when the W-containing Ni—Cr—Mo alloy is subjected to hydrogen chloride gas.

### Example 2

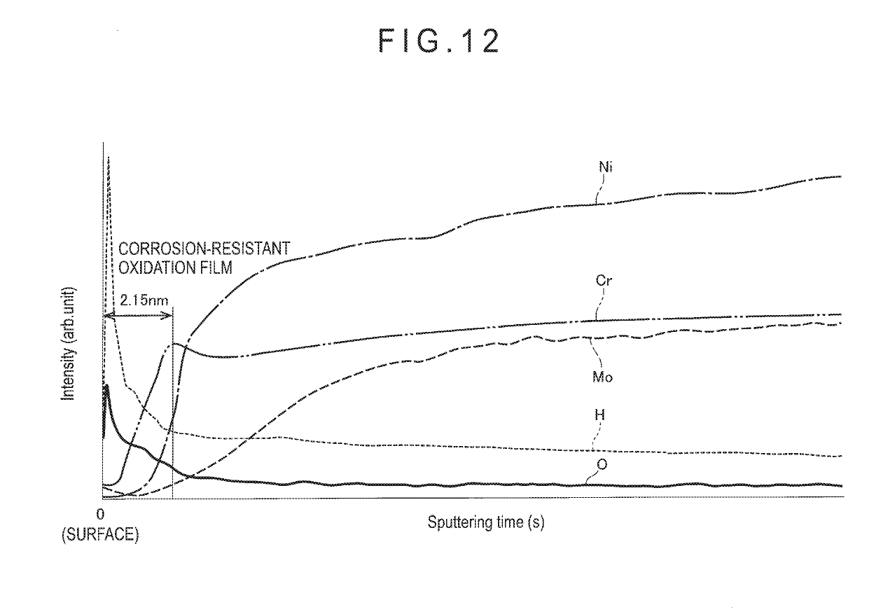

Next, a sample of Example 2 in which the test piece of HASTELLOY C22 was subjected to the passivation treatment and a sample of Comparative Example 2 in which the test piece was not subjected to the passivation treatment were prepared. Then, the samples of Example 2 and Comparative Example 2 were subjected to metal analysis using GD-OES (Glow Discharge-Optical Emission Spectroscopy). The result of Comparative Example 2 is shown in FIG. 12. The result of Example 2 is shown in FIG. 13.

Supposing that the thickness of the corrosion-resistant oxidation film is a half width of a surface strength of O (oxygen), it could be observed that the thickness was 2.15 nm in the sample of Comparative Example 2 shown in FIG. 12, whereas the thickness was increased to be 6.88 nm in the sample of Example 2 shown in FIG. 13. Further, an Ni peak was observed in the corrosion-resistant oxidation film of the sample of Example 2, from which it is speculated that the number of layers of the corrosion-resistant oxidation film is increased.

From the above, it is speculated that the passivation treatment applied on the W-containing Ni—Cr—Mo alloy increases the number and thickness of layers of the corrosion-resistant oxidation film to improve the corrosion resistance of the corrosion-resistant oxidation film.

### Example 3

Next, after cleaning the chamber, an epitaxial silicon wafer of 300 mm diameter was prepared and Experiments of Example 3 and Comparative Example 3 for measuring W concentration on the surface of the epitaxial layer were each conducted for three times.

In Example 3 and Comparative Example 3, the material of the diaphragm 42 of the pressure regulator valve 40 in the decompression unit 32 of the hydrogen-chloride-gas supply apparatus 3, and the material of the component defining the channel in the pressure regulator valve 40 (e.g. the seat 413) were changed as shown in Table 1 below. The material of the diaphragm 52 of the diaphragm valve 50 defining the decompression unit 32 and VMB 33 in the Example 3 and Comparative Example 3 was SPRON 100.

The W concentration was measured by dropping acidic solution on the surface of the epitaxial layer, scanning the surface of the wafer to collect metal impurities on the surface of the epitaxial layer in the solution, and subjecting the collected solution to an ICP-MS quantitative analysis.

The measurement results and average values of the W concentration in the three experiments are shown in Table 2 below.

TABLE 1

| | | Comparative |
|---|---|---|
| | Example 3 | Example 3 |
| Diaphragm | HASTELLOY C22 | SPRON 100 |
| | Passivation treatment: Yes | |
| Channel-Defining | HASTELLOY C22 | HASTELLOY C22 |
| Member | Passivation treatment: Yes | Passivation |
| | | treatment: No |

TABLE 2

W Concentration (atoms/cm²)

| | Example 3 | Comparative Example 3 |
|---|---|---|
| First Time | <1.0 × 10⁵ | 8.0 × 10⁵ |
| Second Time | <1.0 × 10⁵ | 5.3 × 10⁵ |
| Third Time | <1.0 × 10⁵ | 7.2 × 10⁵ |
| Average | <1.0 × 10⁵ | 6.8 × 10⁵ |

As shown in Table 2, while the average of the W concentration on the surface of the epitaxial layer was 6.8×10⁵ atoms/cm² in Comparative Example 3, the W concentration on the surface of the epitaxial layer was 1×10⁵ atoms/cm² or less in Example 3. According to the above results, it can be understood that, with the use of W-containing Ni—Cr—Mo alloy material subjected to the passivation treatment for the material of the diaphragm of the pressure regulator valve (valve) and the component for defining the channel, a high quality epitaxial silicon wafer that is capable of restraining the generation of white defects can be easily produced.

What is claimed is:

1. A method for producing an epitaxial silicon wafer, the method comprising:
applying a vapor deposition on a silicon wafer to produce an epitaxial silicon wafer, wherein
vapor deposition equipment, in which the vapor deposition is conducted, at least comprises a chamber, and a hydrogen-chloride-gas supply apparatus that is in communication and connected with an inside of the chamber to supply hydrogen chloride gas into the chamber,
a valve that comprises a diaphragm configured to regulate a flow of the hydrogen chloride gas from an inlet channel to an outlet channel is disposed in the hydrogen-chloride-gas supply apparatus,
a material of a W-containing Ni—Cr—Mo alloy subjected to a passivation treatment is used for the diaphragm, and
when a maintenance work is to be done to an inside of the chamber, the hydrogen chloride gas is supplied from the hydrogen-chloride-gas supply apparatus into the chamber.

2. The method for producing an epitaxial silicon wafer according to claim 1, wherein
the valve comprising the diaphragm is a pressure regulator valve configured to regulate a pressure of the hydrogen chloride gas flowing therein, and
the material of the W-containing Ni—Cr—Mo alloy subjected to the passivation treatment is used for a component defining a channel in the pressure regulator valve.

3. Vapor deposition equipment configured to apply a vapor deposition on a silicon wafer to produce an epitaxial silicon wafer, the vapor deposition equipment at least comprising:
a chamber; and
a hydrogen-chloride-gas supply apparatus that is in communication and connected with an inside of the chamber to supply hydrogen chloride gas into the chamber, wherein
a valve that comprises a diaphragm configured to regulate a flow of the hydrogen chloride gas from an inlet channel to an outlet channel is disposed in the hydrogen-chloride-gas supply apparatus,
a material of a W-containing Ni—Cr—Mo alloy subjected to a passivation treatment is used for the diaphragm, and
when a maintenance work is to be done to an inside of the chamber, the hydrogen chloride gas is supplied from the hydrogen-chloride-gas supply apparatus into the chamber.

4. The vapor deposition equipment according to claim 3, wherein
the valve comprising the diaphragm is a pressure regulator valve configured to regulate a pressure of the hydrogen chloride gas flowing therein, and
the material of the W-containing Ni—Cr—Mo alloy subjected to the passivation treatment is used for a component defining a channel in the pressure regulator valve.

5. A valve comprising a diaphragm configured to regulate a flow of a gas from an inlet channel to an outlet channel, wherein
the diaphragm comprises a material of a W-containing Ni—Cr—Mo alloy subjected to a passivation treatment.
